(19) United States
(12) Patent Application Publication
(10) Pub. No.: US 2025/0329987 A1
(43) Pub. Date: Oct. 23, 2025

(54) TUNABLE LASER WITH IMPROVED STABILITY

(71) Applicants: Tin Komljenovic, Goleta, CA (US); Minh Tran, Goleta, CA (US); Yang Shen, Goleta, CA (US); Ali Eshaghian Dorche, Goleta, CA (US); Chong Zhang, Santa Barbara, CA (US)

(72) Inventors: Tin Komljenovic, Goleta, CA (US); Minh Tran, Goleta, CA (US); Yang Shen, Goleta, CA (US); Ali Eshaghian Dorche, Goleta, CA (US); Chong Zhang, Santa Barbara, CA (US)

(21) Appl. No.: 18/641,367

(22) Filed: Apr. 20, 2024

(51) Int. Cl. H01S 5/0687; H01S 5/06; H01S 5/10

(52) U.S. Cl. CPC H01S 5/0687; H01S 5/0612; H01S 5/101

(57) ABSTRACT

A device has a first element, having a laser gain element; a second element, optically coupled to the first element, providing a tunable wavelength selective mirror that includes two ring-resonators; a third element, having two heaters, each heater thermally coupled to a corresponding ring-resonator and configured to tune its resonance; and a fourth element, having two sensing elements, each thermally coupled to a corresponding ring-resonator. The ring-resonator waveguide core includes at least one of silicon-nitride, lithium-niobate, tantalum-pentoxide, aluminum-oxide, aluminum-nitride, and silicon. The laser gain element includes at least one of indium, phosphorus, gallium, arsenic, and aluminum. The first, second, third and fourth elements are fabricated on a common substrate, such that a photonic integrated circuit is realized.

### FIELD OF THE INVENTION

The present invention relates to photonic integrated circuits. More specifically, certain embodiments of the invention relate to improved performance of tunable lasers and related components based on photonic integrated circuit technology.

### BACKGROUND OF THE INVENTION

Semiconductor lasers are solid-state lasers based on semiconductor gain media. Most semiconductor lasers are laser diodes, which are pumped with an electrical current in a region where n-doped and p-doped semiconductor materials meet. Common materials for semiconductor lasers (and for other optoelectronic devices) are direct bandgap semiconductors such as GaAs (gallium arsenide), AlGaAs (aluminum gallium arsenide), GaP (gallium phosphide), InGaP (indium gallium phosphide), GaN (gallium nitride), InGaAs (indium gallium arsenide), GaInNAs (indium gallium arsenide nitride), InP (indium phosphide), GaInP (gallium indium phosphide) or others. Indirect bandgap semiconductors such as silicon do not exhibit strong and efficient light emission.

Semiconductor lasers or laser diodes play an important part in our everyday lives by providing cheap and compact lasers used for various applications such as optical communications, sensing, metrology, displays, lighting, material processing and others. Their typical size is in the order of mm, they are made up of complex multi-layer structures requiring nanometer scale accuracy in fabrication and are carefully and elaborately designed for best performance.

A laser is characterized by multiple key parameters such as wavelength of operation, output power, threshold current, wall-plug efficiency, beam quality and others, depending on the application. Of particular interest for many applications are lasers whose wavelength of operation can be altered in a controlled manner; such lasers are commonly called tunable lasers. Tunable lasers are typically single frequency lasers meaning that output power at one frequency is significantly larger than all other peaks in the emission spectrum. The parameter to determine the level of single frequency purity is the side mode suppression ratio (SMSR), defined as the ratio of power in the center peak longitudinal mode to the power in the nearest higher order mode. In some typical cases a threshold of a SMSR >30 dB is considered sufficient to characterize the laser as a single frequency laser. In applications requiring high spectral purity the threshold can be >45 dB or even higher. In yet other applications, where it is hard to provide such high SMSR ratios due to various limitations (e.g. mirror and filter quality), single-frequency lasers can have SMSR of only around 20 dB or lower.

The wavelength of a tunable laser is defined both by the gain medium (defining the spectral range in which lasing is possible) and the cavity comprising the mode-selection filter. There are multiple architectures to provide mode-selection filtering as will be described below, but, in all cases for tunable lasers, one or more controls capable of changing the characteristics of the mode-selection filter are necessary.

Despite the advanced laser designs employed and the high accuracy of semiconductor processing, the output wavelength of a semiconductor laser varies between nominally identically designed devices within a die, between dies across a wafer, and from wafer to wafer, due to differences in layer thicknesses, waveguide widths, sidewall angles, material imperfections and other factors, all of which are present in a practical process. Due to said differences, device calibration is generally necessary.

Calibration is normally performed after fabrication to properly characterize an individual device, and typically utilizes an optical spectrum analyzer or a wavemeter to generate a look-up table (LUT) summarizing the output wavelengths (and, in some cases, other parameters such as e.g. SMSR) as a function of laser control signals (described below). As a laser is operated and ages, this can result in changes in threshold, internal temperatures, defects propagation, physical movements in case of packaged devices (e.g. solder relaxation) limiting the precision of the LUT. This is especially challenging if lasers are to be operated in uncooled environments where ambient temperature can vary over a wide range and provide additional stress to the laser. Due to aging and drift, in some cases the LUT must be re-generated for successful operation of the laser, increasing operational cost, and reducing the useful lifetime of the device.

There is therefore a need for chip-scale tunable semiconductor lasers providing high level of wavelength control and stability that can account for laser aging and changes of external and internal conditions without requiring recalibration. Here we describe such tunable lasers that can generate LUT tables that are stable in the long term, compensating for laser aging and changes in internal and/or external conditions.

### BRIEF DESCRIPTION OF THE DRAWINGS

FIG. 1 (Prior Art) shows a top-down view of a prior art devices.

FIG. 2 (Prior Art) shows a top-down view of a prior art devices.

FIG. 3 (Prior Art) shows simulated responses of frequency selective elements utilized in some types of widely tunable lasers.

FIG. 4 shows a top-down view of a device according to some embodiments of the present invention.

FIG. 5 shows a top-down view of elements of a device according to some embodiments of the present invention.

FIG. 6 shows two cross sections of a device according to some embodiments of the present invention.

FIG. 7 shows one cross section of a device according to some embodiments of the present invention.

FIG. 8 shows one cross section of a device according to some embodiments of the present invention.

FIG. 9 shows one cross section of a device according to some embodiments of the present invention.

FIG. 10 shows one cross section of a device according to some embodiments of the present invention.

FIG. 11 shows top-down view of elements of a device according to some embodiments of the present invention and illustrative calculations of device optimization.

### DETAILED DESCRIPTION

Described herein include embodiments of a heterogeneously integrated tunable laser and related components with improved performance, achieved by leveraging dissimilar materials and adding sensing elements to improve the functionality, performance and reliability.

In the following detailed description, reference is made to the accompanying drawings which form a part hereof, wherein like numerals designate like parts throughout, and in which are shown by way of illustration embodiments in which the subject matter of the present disclosure may be practiced. It is to be understood that other embodiments may be utilized, and structural or logical changes may be made without departing from the scope of the present disclosure. Therefore, the following detailed description is not to be taken in a limiting sense, and the scope of embodiments is defined by the appended claims and their equivalents.

The description may use perspective-based descriptions such as top/bottom, in/out, over/under, and the like. Such descriptions are merely used to facilitate the discussion and are not intended to restrict the application of embodiments described herein to any particular orientation. The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The term “coupled with,” along with its derivatives, may be used herein. “Coupled” may mean one or more of the following. “Coupled” may mean that two or more elements are in direct physical, electrical, or optical contact. However, “coupled” may also mean that two or more elements indirectly contact each other, but yet still cooperate or interact with each other, and may mean that one or more other elements are coupled or connected between the elements that are said to be coupled with each other. The term “directly coupled” means that two or more elements are in direct contact in at least part of their surfaces. The term “butt-coupled” is used herein in its normal sense of meaning an “end-on” or axial coupling, where there is minimal or zero axial offset between the elements in question. The axial offset may be, for example, slightly greater than zero in cases where a thin intervening layer of some sort is formed between the elements, such as e.g. thin coating layer typically used to provide high-reflectivity or anti-reflectivity functionality. It should be noted that the axes of two waveguide structures or elements need not be colinear for them to be accurately described as being butt-coupled. In other words, the interface between the elements need not be perpendicular to either axis in cases e.g. this interface is angled to control the reflections at the interface. No adiabatic transformation occurs between butt-coupled structures/interfaces.

Term “active device”, “active structure” or otherwise “active” element, part, component may be used herein. A device or a part of a device called active is capable of light generation and amplification using electrical contacts. This is in contrast to what we mean by a “passive device” whose principal function is to confine and guide light, and/or provide splitting, combining, filtering and/or other functionalities that are commonly associated with passive devices. Some passive devices can provide functions overlapping with active device functionality, such as e.g. phase tuning implemented using thermal effects or similar that can provide modulation. No absolute distinction should be assumed between “active” and “passive” based purely on material composition or device structure.

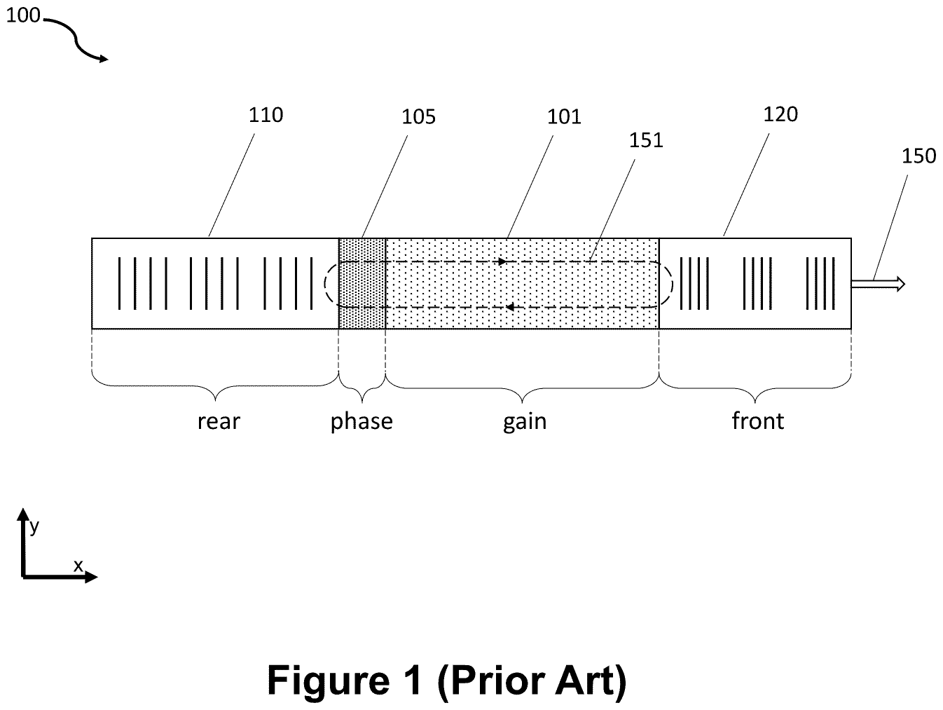

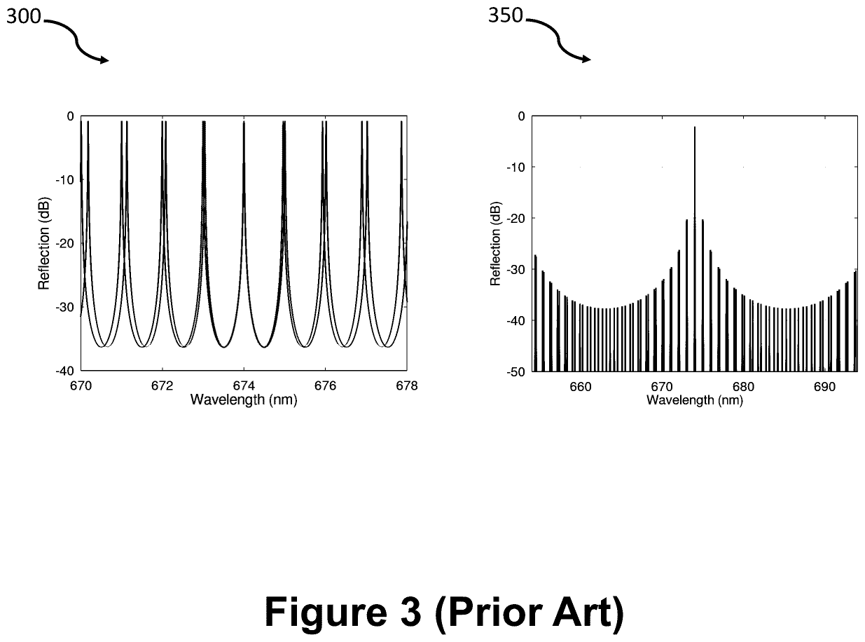

FIG. 1 (prior art) shows a top-down view of a tunable laser device (100) of one category-sampled-grating distributed Bragg reflector (SGDBR) lasers, capable of providing wide tuning ranges. The SGDBR laser (100) comprises four sections: front mirror (120), back mirror (110), gain section (101) and phase section (105). In most embodiments, all four sections comprise III-V materials. The SGDBR laser mirrors, in some embodiments, have different reflectivities with one mirror (front mirror (120) in the embodiment shown) having lower reflectivity and consequently outputting more power from the circulating optical field (151) in the direction (150) passing through the lower reflectivity mirror to emerge as an output beam. Each of the mirrors (110) and (120) is realized as a sampled periodic structure (grating), resulting with multiple reflectivity peaks in spectral domain. These peaks are spaced apart in the spectral domain at a period inversely proportional to the period of the sampling of the grating in the physical space. The two mirrors of the laser are sampled at different periods such that substantially only one of their multiple reflection peaks coincided in the optical bandwidth range defined by the gain medium, as may be understood in terms of the Vernier effect (see also FIG. 3). Narrow-band tuning, performed by careful control of all tuning signals, allows continuous tuning over a limited range (GHz range nominally). Wide-band tuning is realized utilizing the Vernier effect between said mirrors. When providing wide-band tuning, the laser can mode-hop producing both phase and frequency discontinuities. SGDBR lasers can provide several THz of tuning range or even more (with mentioned mode-hops), but due to fabrication imperfections, packaging and other effects discussed above the output wavelength varies between nominally identical devices driven with identical control signals.

The tuning of mirrors can utilize thermal or carrier (plasma) effects in their III-V materials to change the refractive index and consequently the wavelength at which the periodic structure in each mirror provides reflection/feedback to the gain section. A look-up table (LUT) can be generated corresponding to the drive conditions (e.g. current supplied to each mirror) needed for the laser to operate at each particular wavelength. Additionally, the phase section can be tuned to align the longitudinal modes to the peak of mirror reflectivity and improve laser performance. The LUT is commonly generated by sweeping the control signals applied to the mirrors (and the phase section) and recording the output wavelength, and other relevant parameters (e.g. SMRS, output power). If the relevant parameters are considered acceptable, the settings and corresponding wavelengths can be stored in e.g. memory and the laser can be controllably tuned to the desired wavelength condition using the stored settings. The problem is that lasers typically age, resulting in changes in their parameters including threshold, output power, differential efficiency, etc. Furthermore, mirrors comprise similar materials as the gain section, both of which often comprise III-V materials (such as InP, GaAs, GaN and their ternaries and quaternaries) and can also exhibit aging due to currents and thermal cycling.

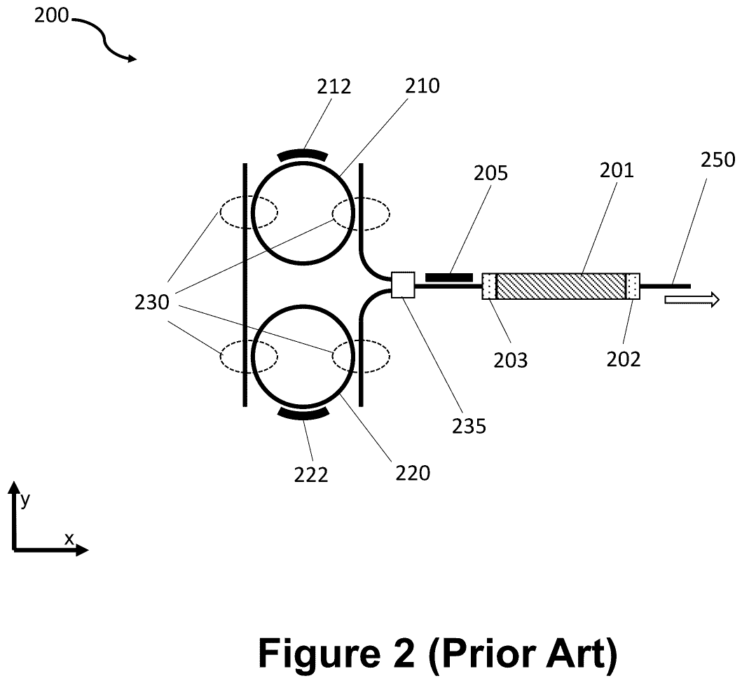

FIG. 2 (prior art) shows a top-down view of a tunable laser device (200) of a second category-ring-resonator-based (RRB) lasers, capable of providing wide tuning ranges. At least two ring resonators (210) and (220) in add-drop configuration are used to provide frequency-selective feedback, with each resonator having at least two coupling regions (230). Coupling regions are, in some embodiments, directional or pulley couplers in which coupling strength can be well controlled and coupler losses optimized. Each ring has multiple resonances in the frequency/wavelength domain, as shown in view (300) in FIG. 3, with their spacing determined by the free-spectral range corresponding to the inverse of the round-trip time inside each resonator. By designing two (or more) ring resonators to have slightly different round-trip times, wide tuning can be realized in their combined output utilizing the Vernier effect as shown in view (350) in FIG. 3.

In the embodiment shown in view (200), the light from gain region (201) is coupled to the ring-resonator region via coupling element (203) and splitter (235). In most embodiments, the material from which the gain region is made (commonly III-V material), and the material from which the resonators are made are substantially different. In some embodiments, the resonators are made from Si (silicon) using a heterogeneous silicon platform, in some other embodiments the resonators are made from materials such as SiN (silicon-nitride), SiONx (silicon-oxynitride), TiO2 (titanium-dioxide), Ta2O5 (tantalum-pentoxide), LiNbO3 (lithium-niobate), Al2O3 (alumina) and AlN (aluminum-nitride). This is distinctly different from the case of SGDBR lasers described with the help of FIG. 1 where both the gain and mirrors (providing frequency selective feedback similar to resonators in RRB lasers) are made from the same or similar III-V materials.

In all cases of RRB lasers, it is preferred that propagation loss in the waveguides from which the resonators are formed is low, that the waveguides support sufficiently small bend radiuses (without excess loss), and support relatively high waveguide powers (due to power buildup typically encountered inside a resonant element). Each resonator (e.g. 210 and 220) has a tuning element (e.g. 212 and 222), and in most cases the tuning element is a heater that can change the resonant condition/wavelength of the resonator by changing the effective index via the thermo-optic coefficients of the materials that are used to form the waveguide of the resonator.

In some embodiments, RRB lasers also comprise a phase tuner (205) that enables tuning of the longitudinal modes, and alignment of the longitudinal mode locations to the frequency response of the resonators. The phase tuner, in most cases, is also a heater that changes the effective index of the waveguide via its own thermo-optic coefficient.

The tuning of RRB lasers is similar to the tuning of SGDBR lasers as described above with multiple control signals (to the resonators and the phase tuner), but due to the generally higher quality filtering provided by ring-resonators compared to gratings, tuning ranges larger than 10 THz can be provided. Also similarly to SGDBR lasers, the output wavelength of RRB lasers varies between nominally identical devices driven with identical control signals, due to fabrication imperfections, packaging and other effects.

The light from gain region (201) is coupled to output waveguide (250) via coupling element (202) and a front mirror. The front mirror is not explicitly shown in this figure but can be realized in multiple ways in different embodiments, such as e.g. a facet mirror in gain region, a loop mirror in the output waveguide, a grating in the output waveguide etc.

Other arrangements of resonators in RRB lasers are possible, including changing their positions, coupling locations, and/or number, or adding loop-mirrors to provide desired frequency selectivity and insertion loss as is known in the art of RRB lasers.

FIG. 3 (prior art) shows illustrative frequency responses of two ring resonators with the different lengths of the waveguides in the resonators resulting in different free-spectral ranges (view 300) and providing a useful combined frequency response (view 350). As the responses of the two rings are slightly different—by having the free-spectral ranges offset by a small amount-their responses only align well at one single frequency in a broadband wavelength range, allowing that corresponding single longitudinal mode to be selected to provide single-frequency lasing. Furthermore, this allows tuning over the full tuning range with relatively low drive power, as each ring only has to be tuned by one free-spectral range to cover a much broader output wavelength range using the Vernier effect. At the same time, however, this results in challenges related to the quality of LUTs, as changes of external conditions or laser aging can cause the laser to jump to a “wrong” wavelength.

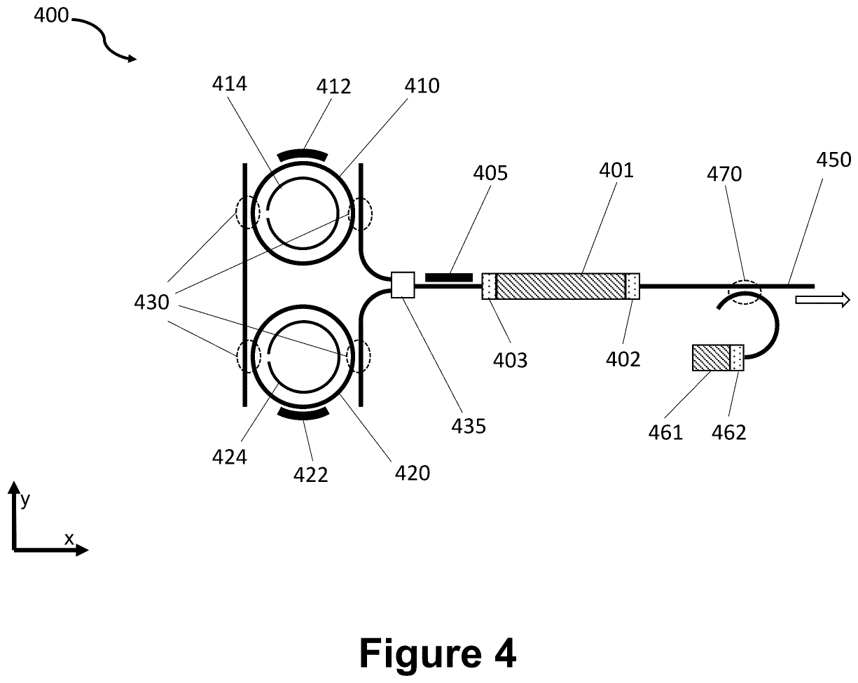

FIG. 4 shows a top-down view of a tunable laser device corresponding to some embodiments of present invention. The tunable laser device (400) is a ring-resonator-based (RRB) laser (therefore intrinsically able to provide a wide tuning range) but it differs from RRB laser 200 in including monitor elements (414) and (424) that help provide long term stability of the LUTs as will be described below. In some embodiments, the tunable laser also comprises a monitor photodetector (461) coupled to the laser gain region 401 via a tap coupler (470) and coupling element (462). The monitor photodetector 461 tracks the power emitted by the laser through coupling element 402. Tap coupler (470) usually taps a small part, often between 0.1% and 10%, of the light reaching it from the laser, coupling the rest of the laser's output light into output waveguide 450. Elements (401) to (450) correspond to layers (201) to (250), unless explicitly defined differently, as described in relation to FIG. 2.

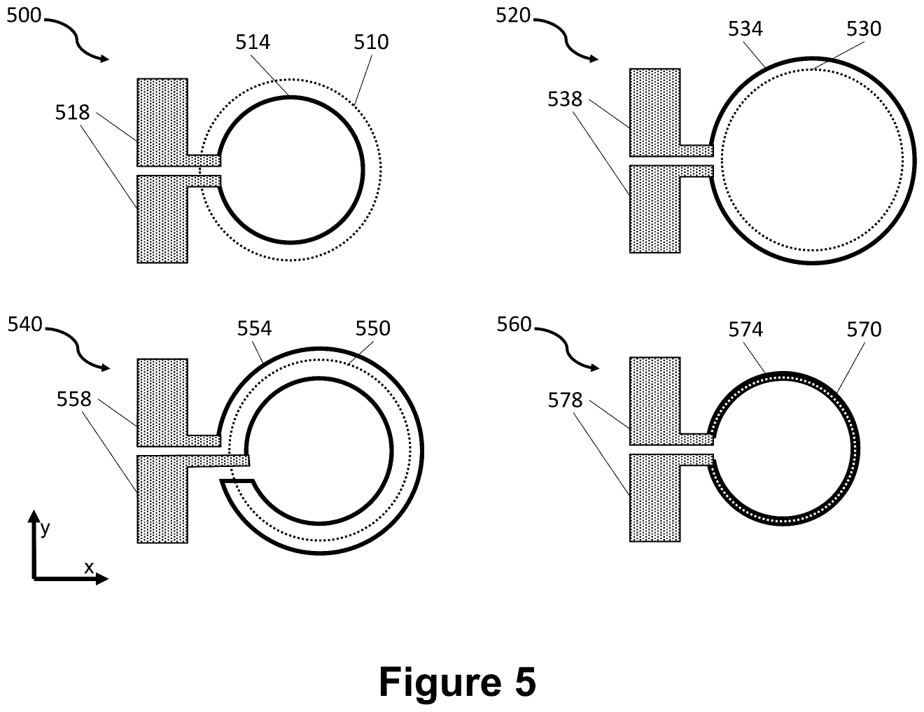

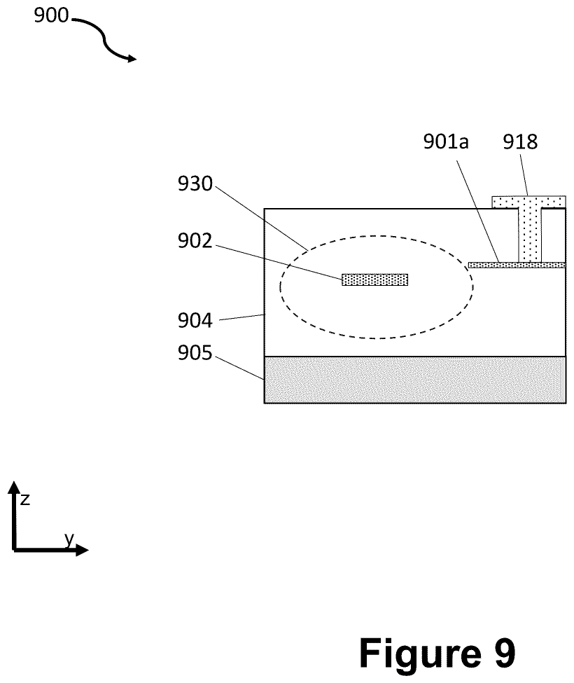

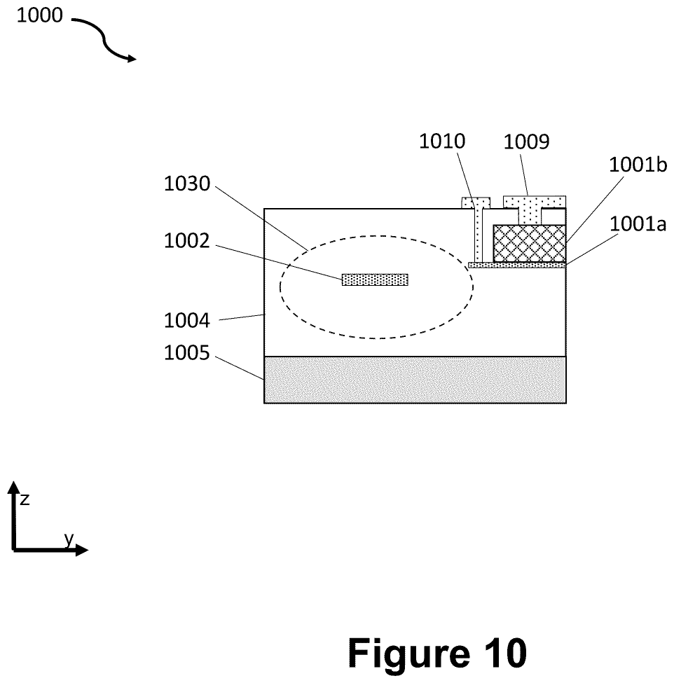

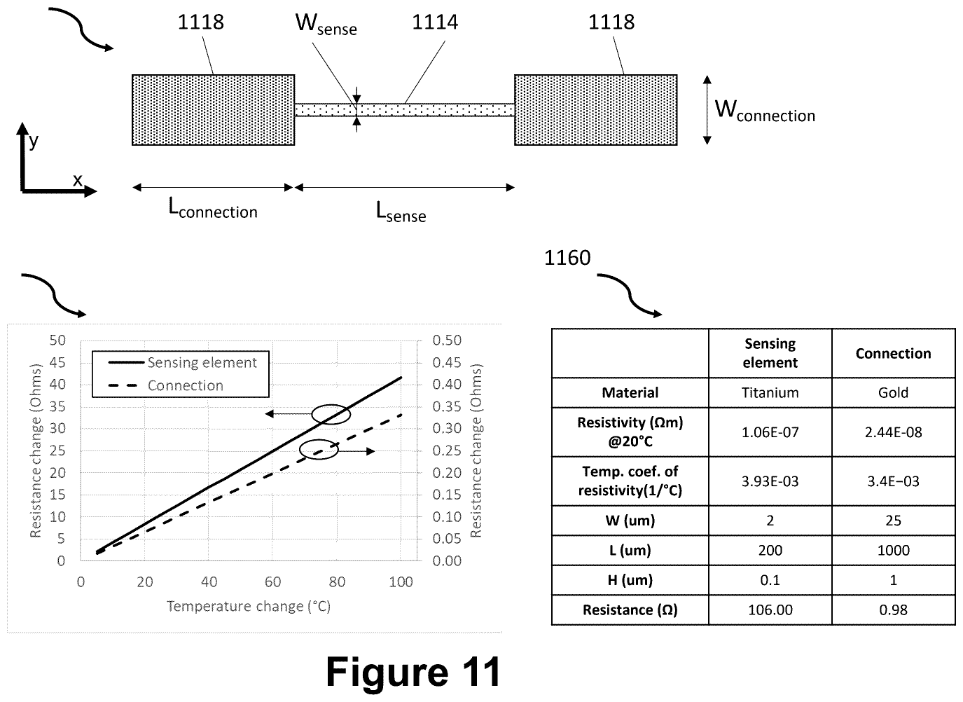

Monitor elements (414/424), in some embodiments, comprise materials whose resistance varies with temperature. Examples of such materials include metals and semiconductors. Metal resistance generally increases with temperature, while semiconductor material resistance generally decreases with temperature. In some other embodiments, as will be described in more detail in the discussion of FIGS. 9 and 10, pn-junctions can be used to monitor temperature, as pn-junctions usually exhibit a change in dark current and a change in turn-on voltage as a function of temperature. Monitor elements are shaped and positioned such that they have significant thermal coupling with the resonator elements, e.g. monitor element (414) follows the shape of the resonator (410). More details will be provided in the discussion of FIGS. 5 and 11.

A LUT typically needs to be generated to allow a tunable laser to be tuned. In past generations of tunable lasers, the LUT would usually record the driving conditions of whatever tuning elements are used, e.g. in the case of thermal tuners one would record the power delivered to the tuner (either as power, current and/or voltage) corresponding to the particular wavelength of operation. Although this approach enables initial laser tuning, over a limited temperature range, it has issues when the laser is operated over an extended temperature range, requiring multiple LUTs to cover all the operating temperatures of interest, but even multiple LUTs cannot account for the effects of laser aging. As discussed above, aging can change the internal thermal distribution of an RRB laser resulting in a change of resonator temperature for a particular drive condition, in turn leading to the laser operating at a “wrong” wavelength, i.e. a wavelength other than that suggested by prior art LUTS.

In the case of SGDBR lasers, aging of the III-V tunable mirrors necessarily changes the wavelength response at a particular current. In prior art RRB lasers, aging necessarily changes thermal profiles across the tunable resonators and therefore changes the wavelength.

The present invention in contrast, deliberately makes use of the fact that the key performance requirements of interest in the laser output (wavelength, SMSR etc.) are determined by the spatially distributed thermal environment experienced by the resonator waveguides, which is determined not only by user-adjustable settings such as drive current, but also by uncontrolled changes caused by device aging. In embodiments of the type shown in FIG. 4, therefore, the LUT is generated by focusing on the thermal conditions experienced by the resonators, to take both types of influences into account. The thermal conditions are determined by monitor elements (414, 424) in terms of monitor resistance (or dark current or turn-on voltage, depending on the type of monitor elements present) which are indicative of temperatures actually experienced along the ring resonator waveguides. By appropriate shaping and positioning of the monitor elements, good indication of the effective integrated thermal distribution is attainable. The LUT stores values of resistance (or dark current or turn-on voltage) and corresponding, measured laser output characteristics. In subsequent device operation, rather than selecting particular drive currents (or voltages or powers) to achieve a desired laser characteristic (e.g. wavelength) or a desired combination of laser characteristics, those drive variables are adjusted until the monitor elements' readings match the values of resistance (or dark current or turn-on voltage) recorded in the LUT as corresponding to that or those characteristics.

In many cases, the resonators are defined in the types of dielectric materials listed in relation to FIG. 2, resulting in resonators that exhibit essentially no aging. For example, in a case where resonators are defined using SiN as the core and SiO2 as the cladding, as both materials are extremely stable in terms of aging, one only needs to precisely measure the temperature to be able to predict the wavelength response of the whole laser with confidence, both during calibration and under extended operation, regardless of aging-related changes affecting regions other than the resonator.

FIG. 5 shows four top-down views (500, 520, 540, 560) of four embodiments of a resonator and monitor element. The monitor element (514, 534, 554, 574) is typically positioned such as to have significant interaction length with the resonator (510, 530, 550, 570) allowing it to better measure the distributed temperature of the resonator. The distributed temperature changes the effective index of the resonator according to the thermo-optic coefficient of the materials that are used to form the waveguide inside the resonator. In all cases, the monitor element is electrically connected to a circuit that can measure either resistance, dark current and/or turn-on voltage. For the cases where measurement of the change of resistance is utilized, it is beneficial to make the electrical connections (518, 538, 558, 578) have much smaller resistance than the monitor element as will be described in more detail in relation to FIG. 11.

In view 500, the monitor element (514) has a long interaction length with the resonator (510) by being placed slightly inside the perimeter of that resonator. In view 520, the monitor element (534) has a long interaction length with the resonator (530) by being placed slightly outside the perimeter of that resonator. In view 540, the monitor element (554) has a long interaction length with the resonator (550) by being positioned and laid out to be close to and bound the resonator waveguide from the inside and the outside of its perimeter over a significant fraction of that length. In view 560, the monitor element (574) has a long interaction length with the resonator (570) by being placed close to and overlapping the resonator. Of course, various other arrangements are possible with the same goal of matching the distributed monitor elements to the resonator waveguides along a significant fraction of the waveguides' length to better monitor the thermal distribution impacting those waveguides. In some embodiments (not shown), multiple monitors can be utilized for each resonator.

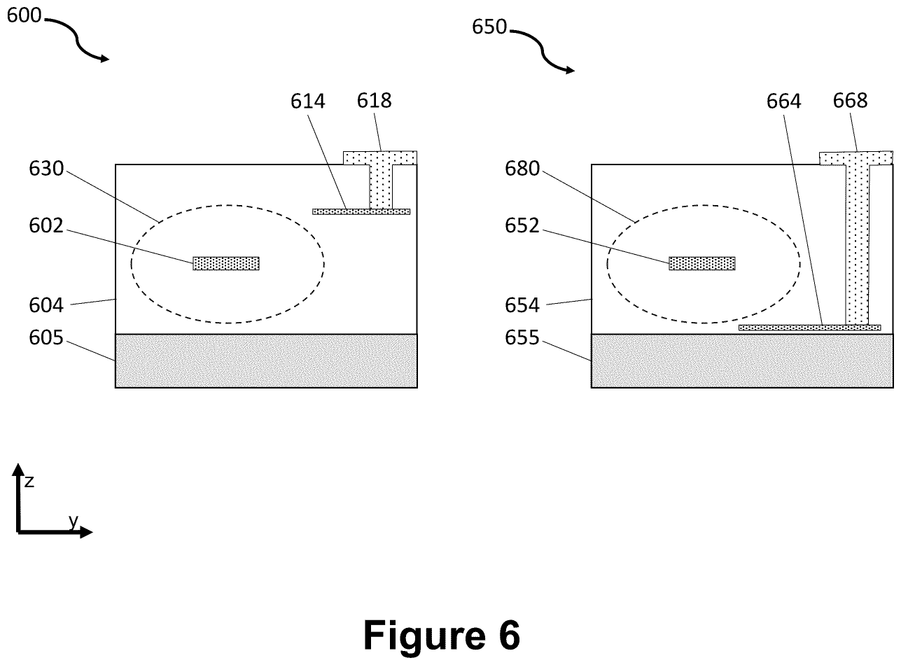

FIG. 6 shows cross section views of devices (600, 650) according to some embodiments of the present invention. The resonator waveguide core (602, 652) in combination with its cladding (604, 654) and overlying substrate (605, 655) supports an optical mode (630, 680). Monitor elements (614, 664) are electrically connected to an unshown sensing circuit via electrical connections (618, 668) that, in the case of measuring resistance to determine temperature, preferably have much smaller resistance than the monitor element as will be described in relation to FIG. 11. Defining height along the z axis indicated in FIG. 6, in the device shown in view 600 the monitor element is positioned in a plane above the waveguide, in the device shown in view 650 the monitor element is positioned in a plane below the waveguide, and in some other cases (not shown) the monitor element can be at substantially the same height as that of the waveguide. In all embodiments, the monitor element is placed close enough to the waveguide to sense the waveguide temperature, but at a sufficient distance from the effective boundary of the optical mode to not cause increased propagation losses. This distance can be optimized using e.g. commercial electromagnetic solvers.

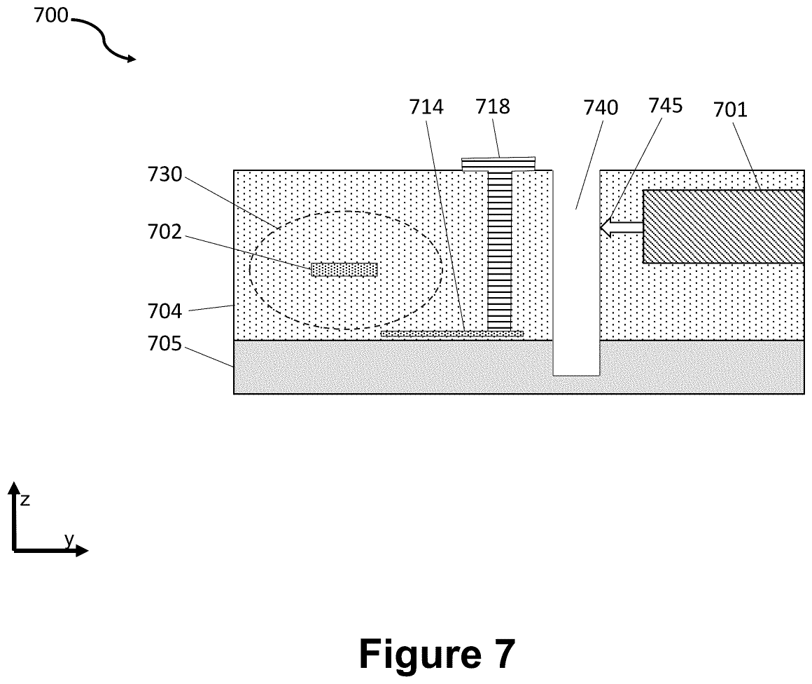

FIG. 7 shows a cross section view of a device (700) according to some embodiments of the present invention where a trench (740) is introduced to better isolate the regions where the temperature of the resonator is measured. In this example, trench (740) is etched between the active element (701), corresponding to element (401) as described in relation to FIG. 4, and the resonator waveguide (702) corresponding to at least one of the resonators (410, 420) of the RRB laser as described in relation to FIG. 4. The trench, serving to locally increase thermal impedance, can improve the device in at least two ways. First it can improve the efficiency of tuning elements by localizing delivered heat, and second it reduces the amount of the heat emerging from the active element reaching the resonator and monitor element region as suggested by arrow (745). Functional layers (704) to (718), unless explicitly defined differently, correspond to functional layers (654) to (668) as described in relation to FIG. 6, and optical mode (730) corresponds to optical mode (680) as described in relation to FIG. 6. The trench (740) shown in FIG. 7 is simply formed by the z-axis removal of the full depth of cladding (704) and at least part of the depth of substrate (705), but in some other embodiments (not shown) a trench can also utilize some undercutting of the substrate (along the y-axis) or some other similar process options to further improve thermal shielding between a gain region and a resonator.

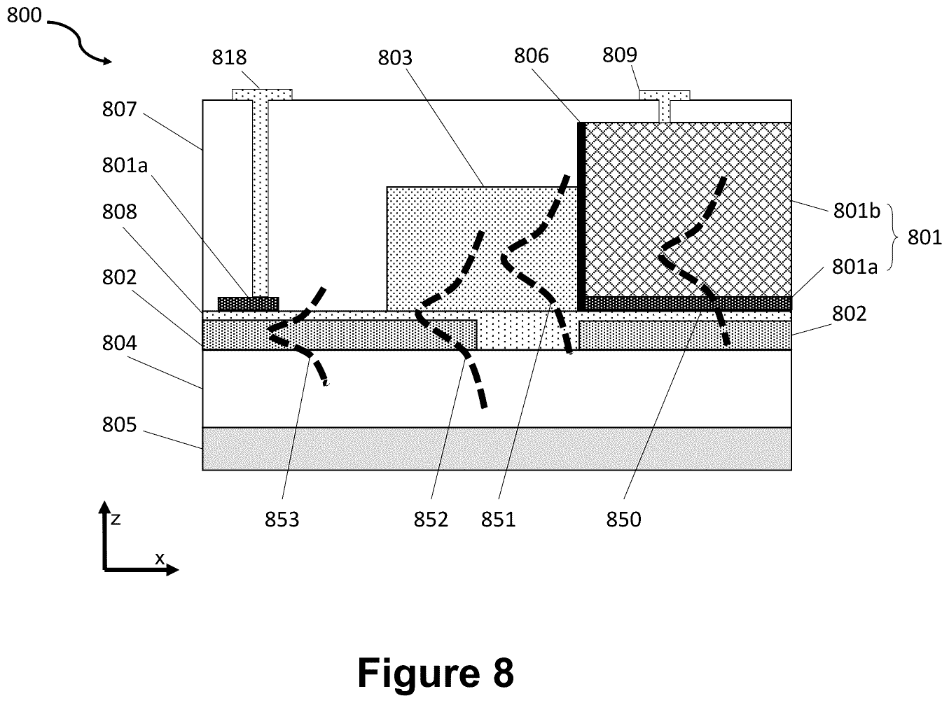

FIG. 8 is a schematic cross-section view of an integrated photonic device (800) utilizing butt-coupling and mode conversion for efficient coupling between dissimilar materials to realize a tunable laser. It also utilizes a semiconductor layer (801a) as a sensing element as will be described below. Functional layers (802) to (805), unless explicitly defined differently, correspond to functional layers (602) to (605) as described in relation to FIG. 6.

Substrate (805) can be any suitable substrate for semiconductor and dielectric processing, such as Si, InP, GaAs, quartz, sapphire, glass, GaN, silicon-on-insulator or other materials known in the art. In the shown embodiment, a layer of second material (804) is deposited, grown, transferred, bonded or otherwise attached to the top surface of substrate (805) using techniques known in the field. The main purpose of layer (804) is to provide optical cladding for material (802), if necessary to form an optical waveguide. Optical waveguides are commonly realized by placing higher refractive index core between two lower refractive index layers to confine the optical wave. In some embodiments, layer (804) is omitted and substrate (805) itself serves as a cladding.

Layer (802) is deposited, grown, transferred, bonded or otherwise attached to the top of layer (804) if present, and/or to the top of substrate (805), using techniques known in the field. The refractive index of layer (802) is higher than the refractive index of layer (804) if present, or, if layer (804) is not present, the refractive index of layer (802) is higher than the refractive index of substrate (805). In one embodiment, the material of layer (802) may include, but is not limited to, one or more of SiN (silicon-nitride), SiONx (silicon-oxynitride), TiO2 (titanium-dioxide), Ta2O5 (tantalum-pentoxide), LiNbO3 (lithium-niobate), Al2O3 (alumina) and AlN (aluminum-nitride). In other embodiments, a semiconductor material may be used for layer (802). Examples of suitable semiconductor materials are Si (silicon), GaN (gallium-nitride), GaAs (gallium-arsenide), AlGaAs (aluminum-gallium-arsenide), InP (indium-phosphide), or similar materials, usually characterized by a bandgap wavelength that is shorter than the desired wavelength of laser operation.

Layer (808), whose refractive index is lower than the refractive index of layer (802) serves to planarize the patterned surface of layer (802). The planarization may be controlled to leave a layer of desired, typically very low, thickness on top of the layer (802) (as shown in FIG. 8), or to remove all material above the level of the top surface of the layer (802) (not shown). In cases where layer (808) is left on top of layer (802), the target thicknesses are in the range of 10 nm to several hundreds of nm, with actual thickness, due to planarization process non-uniformities, being between zero and several hundreds of nanometers larger than the target thickness. The top surface of layer (808) is typically characterized by a low surface roughness which makes it suitable for bonding. In some cases, the roughness is <5 nm RMS, in yet other embodiments it is <1 nm RMS. It is generally known that bonding yield is improved as surface roughness is reduced. A good CMP process can produce surface roughness <0.5 nm RMS or lower (better).

Layer (801) is bonded on top of at least part of the corresponding (808, 802) top surface. The bonding can be direct molecular bonding, or additional materials can be used to facilitate bonding such as e.g. polymer films as is known in the art. The bonding material, if used, has to have reasonably low losses at the wavelength of operation as the optical modes (850, 853) have some overlap with the bonding material. Layer (801) makes up what is commonly called an active device, gain region or gain section, and is made up of materials including, but not limited to, GaAs, InP and/or GaN based ternary and quaternary materials. Layer (801) is multilayered, comprising sublayers providing both optical and electrical confinement as well as electrical contacts, as is known in the art for active devices. In the embodiment shown in FIG. 8, layer (801) comprises two distinct sublayers (801a) and (801b), both of which can comprise additional sublayers. Sublayers of layer (801) in some embodiments provide vertical confinement (up/down in FIG. 8, z-axis), while lateral confinement (the lateral direction would correspond to the unshown y-axis, which is not visible in this cross-section) is provided by at least one etch as is known in the art for active devices.

Sublayer (801a) comprises, at minimum, one III—V based semiconductor sublayer suitable for forming ohmic contacts to metal (818). Moreover, the resistivity of sublayer (801a) is a function of temperature allowing the realization of a sensing element as will be described in more detail with the help of FIG. 9.

In some embodiments, as shown in FIG. 8, sublayer (801b) is removed from the top of layer (801a) in regions (like that shown on the left if FIG. 8) where it is desired to make resistivity-based measurements indicative of temperature using sublayer (801a).

Sublayer (801b) comprises, at minimum, one III—V based semiconductor sublayer suitable for forming ohmic contacts to metal (809), and in some unshown embodiments, for forming a pn-junction inside combined sublayers (801a/801b). The pn-junction is characterized by dark current and turn-on voltage values both of which depend in part on choice of materials, doping levels and semiconductor processes but once fabrication is complete the measured dark current and turn-on voltage will also depend on temperature, allowing for the realization of a sensing element as will be described in more detail with the help of FIG. 10. In these unshown embodiments, both sublayer (801a) and (801b) would be present on the left side of FIG. 8 to provide a suitable pn-junction there for measurements indicative of temperature.

Efficient coupling between optical mode (850) supported in the active structure (801) and optical mode (853) supported in a passive waveguide for which layer (802) provides the core is facilitated by layer (803), and, in cases where layer (806) is present, by layer (806). Optional layer (806) primarily serves as either an anti-reflective or a highly reflective coating at the interface between layer (801) and layer (803). Layer (803) serves as an intermediate waveguide that in some embodiments accepts the profile of an optical mode (850) supported by the waveguide for which layer (801) provides the core, captures it efficiently as mode profile (851), and gradually transfers it first to mode profile (852), and finally to mode profile (853). Mode profile (853) is efficiently coupled to the waveguide for which layer (802) provides the core. In some embodiments, the intermediate waveguide corresponds to coupling elements (e.g. 202, 203, 402, 403, 462).

The use of intermediate layer (803) significantly improves efficient transfer between high refractive index III-V materials (801) and low refractive index materials used as waveguide (802). In some embodiments, layer (808) is not present and both layers (801) and (803) are positioned on top of a patterned layer (802), layer (801) by bonding, and layer (803) by any of various deposition methods. In such embodiments, there is no planarization step.

FIG. 9 shows a cross section view of a device (900) according to some embodiments of the present invention where a semiconductor doped layer (901a), corresponding to layer (801a) as described in relation to FIG. 8, acts as a monitor element used to measure temperature as indicated by a change of resistance. Monitor element (901a) is connected to a sensing circuit (not shown) via an electrical path that includes contacts (918). As monitor element (901a) uses a semiconductor material to measure change of resistance, contact (918) is optimized such as to form ohmic contacts to the semiconductor (901a). In some embodiments, layer (901a) comprises at least one of InP, GaAs, and InGaP, suitably doped to provide an optimized resistance that can be reliably measured as a function of temperature. The relationships between specific doping levels and resistivity for each material can be efficiently calculated/simulated using approximate expressions or using more advanced simulation tools. Functional layers (902) to (905), unless explicitly defined differently, correspond to functional layers (602) to (605) as described in relation to FIG. 6, and optical mode (930) corresponds to optical mode (630) as described in relation to FIG. 6.

FIG. 10 shows a cross section view of a device (1000) according to some embodiments of the present invention where a semiconductor pn junction formed inside combined layers (1001a/1001b), corresponding to layers (801a/810b) as described in the discussion of FIG. 8, acts as a monitor element used to measure temperature as indicated by a change of dark current and/or turn-on voltage. The monitor element is connected to a sensing circuit (not shown) via an electrical path that includes contacts (1010, 1009) that are optimized such as to form ohmic contacts to the semiconductors (1001a) and (1001b) respectively. Functional layers (1002) to (1005), unless explicitly defined differently, correspond to functional layers (602) to (605) as described in relation to FIG. 6, and optical mode (1030) corresponds to optical mode (630) as described in relation to FIG. 6.

FIG. 11 shows a top-down view of some embodiments of a device (1100) according to the present invention, illustrative calculations (1130) detailing the benefits of utilizing an embodiment of device (1100), and a table (1160) with some illustrative parameters related to the choice of sensing element and electrical connections in such embodiments. The top-down view of device (1100) illustrates the geometrical relationships for the sensing element (1114) and electrical connections (1118). In this view, both the sensing element and electrical connections are shown as being rectangular blocks with different fixed widths and lengths, but in many embodiments, they can have curved outer and inner sides to e.g. better match the shape of the resonator and can also have varying widths. In view (1110) we define the width for both the sensing element (Wₛₑₙₛₑ) and electrical connections (W_{connection}) in the vertical (y-axis) direction, and we define length for both the sensing element (Lₛₑₙₛₑ) and electrical connections (L_{connection}) in the horizontal (x-axis) direction. Their heights (or thicknesses) of are not visible in this view but would be visible in the z-axis that is not shown in this view. This is illustrative, and any other description for three key dimensions characterizing the elements can be used without departing from the spirit of invention.

In this illustrative example, the sensing element is primarily made from titanium and the electrical connections are primarily made from gold, but any other suitable materials can be used. Characteristic parameters for selected metals are summarized in table (1160) including resistivity at 20° C. and temperature coefficients of resistivity describing the change of resistivity as a function of temperature. As described earlier, it is preferred that the resistance of electrical connections be significantly smaller than the resistance of the sensing element, or in other words it is beneficial to maximize the change of the resistance as a function of temperature in the sensing element vs any change of resistance of the electrical connections to enhance the quality of the measurement as the major part of the total resistance change will then come from the sensing element, that is suitably positioned around and close to the resonators. In this illustrative case, this can be done in two ways: (1) by suitable selection of materials for both elements and (2) with geometrical optimization of the dimensions of both elements. The selection of materials allows for some difference in resistivities, e.g. by choosing titanium and gold we can utilize the ˜4× difference in resistivity of the materials, but geometrical optimizations enable us to make the effect of that difference significantly larger. In the illustrative case, despite the shorter length (5× less) of the sensing element, its resistance can be made significantly higher (˜100×) than that of each connection by adjusting the widths and thicknesses accordingly, as shown in the table. This enables the sensing element to be placed around and close to the resonator while at the same time supporting the longer routing of the electrical connections that may be needed to connect to the sensing circuit (not shown) that measures the total resistance change as a function of temperature.

Finally, the impact of these optimizations is shown in plot (1130) where the changes of resistance of the sensing element and the (electrical) connections are plotted. Note that two y-axes are utilized, and the resistance change differs by ˜2 orders of magnitude for the two elements. This suggests that for the combined structure comprising both, the majority of the resistance change will be a function of the temperature of the sensing element which as noted above is the preferred case for the present invention. In some embodiments, the difference in resistance between the sensing element and (electrical) connections is at least 10×. In yet other embodiments, including the one illustrated in plot (1130), it is greater than 100×.

It is to be understood that these illustrative embodiments teach just several examples of heterogeneously integrated tunable lasers utilizing present invention and many similar arrangements can be further envisioned. Furthermore, such lasers can be combined with multiple other components to provide additional functionality or better performance such as various filtering elements, amplifiers, monitor photodiodes, modulators and/or other photonic components.

Embodiments of the present invention offer many benefits. The integration platform enables scalable manufacturing of lasers and PICs made from multiple materials providing higher-performance and/or ability to operate in particular wavelength range.

This present invention utilizes a process flow consisting typically of die/wafer-bonding of a piece or wafer of compound semiconductor material to waveguides defined on a substrate wafer and subsequent semiconductor fabrication processes known in the art. It enables an accurate definition of optical alignment between active and passive waveguides using common alignment marks and advanced lithography, removing the need for precise physical alignment. Said lithography-based alignment allows for scalable manufacturing using wafer scale techniques.

Embodiments of the optical devices described herein may be incorporated into various other devices and systems including, but not limited to, various computing and/or consumer electronic devices/appliances, industrial systems, communication systems, quantum systems, medical devices, sensors and sensing systems and other areas that can benefit from small size illuminators.

It is to be understood that the disclosure teaches just few examples of the illustrative embodiment and that many variations of the invention can easily be devised by those skilled in the art after reading this disclosure and that the scope of the present invention is to be determined by the following claims.

1. A device comprising:
a first element, comprising a laser gain element;
a second element, providing a tunable wavelength selective mirror comprising two ring-resonators, optically coupled to the first element;
a third element, comprising two heaters, each heater being thermally coupled to a corresponding one of the two ring-resonators and configured to tune the resonance of that ring-resonator;
a fourth element, comprising two sensing elements, each sensing element being thermally coupled to a corresponding one of the two ring-resonators;
wherein the ring-resonator waveguide core comprises at least one of silicon-nitride, lithium-niobate, tantalum-pentoxide, aluminum-oxide, aluminum-nitride, and silicon;
wherein the laser gain element comprises at least one of indium, phosphorus, gallium, arsenic and aluminum; and
wherein first, second, third and fourth elements are fabricated on a common substrate, such that a photonic integrated circuit is realized.

2. The device of claim 1,
wherein the sensing element comprises a metal; and
wherein the metal is characterized by a resistivity which is a function of temperature.

3. The device of claim 1,
wherein the sensing element comprises a doped semiconductor; and
wherein the doped semiconductor is characterized by a resistivity which is a function of temperature.

4. The device of claim 1,
wherein the sensing element is a pn-junction; and
wherein the pn-junction is characterized by a dark current which is a function of temperature.

5. The device of claim 1,
wherein the sensing element is a pn-junction; and
wherein the pn-junction is characterized by a turn-on voltage which is a function of temperature.

6. The device of claim 1,
wherein at least one trench provides thermal isolation between the first element and the second element.

7. The device of claim 1,
wherein a fifth element is fabricated on the common substrate; and
wherein the fifth element comprises a monitor photodetector, optically coupled to an output from the laser gain element.

8. The device of claim 2,
wherein each of the sensing elements in the fourth element additionally comprises two connection elements connected in series; and
wherein each of the sensing elements has a first resistance at least 10 times larger than a second resistance characterizing the series of the corresponding two connection elements.
